(19) United States
(12) Patent Application Publication
(10) Pub. No.: US 2018/0347029 A1
(43) Pub. Date: Dec. 6, 2018

(54) MICRO EVAPORATOR, OSCILLATOR INTEGRATED MICRO EVAPORATOR STRUCTURE AND FREQENCY CORRECTON METHOD THEREOF

(71) Applicant: SHANGHAI INSTITUTE OF MICROSYSTEM AND INFORMATION TECHNOLOGY, CHINESE ACADEMY OF SCIENCES, SHANGHAI (CN)

(72) Inventors: HENG YANG, SHANGHAI (CN); WEILONG YOU, SHANGHAI (CN); LEI ZHANG, SHANGHAI (CN); XIAOFEI WANG, SHANGHAI (CN); XINXIN LI, SHANGHAI (CN)

(73) Assignee: SHANGHAI INSTITUTE OF MICROSYSTEM AND INFORMATION TECHNOLOGY, CHINESE ACADEMY OF SCIENCES, SHANGHAI (CN)

(21) Appl. No.: 15/774,590

(22) PCT Filed: Jan. 6, 2016
(86) PCT No.: PCT/CN2016/070284

§ 371 Date: Aug. 22, 2018

(30) Foreign Application Priority Data
Nov. 25, 2015 (CN) 201510833446.7

(51) Int. Cl. C23C 14/24; H03H 9/24; H03B 1/02; H01L 21/02

(52) U.S. Cl. CPC C23C 14/24; H03H 9/24; H03B 1/02; H01L 21/02631; H01L 21/02488; H01L 21/0242; H01L 21/02491

(57) ABSTRACT

The present invention provides a micro evaporator, an oscillator integrated micro evaporator structure and a frequency correction method thereof. The micro evaporator comprises a micro evaporation platform, anchor points, supporting beams and metal electrodes, wherein one surface of the micro evaporation platform is an evaporation surface; the anchor points are located on two sides of the micro evaporation platform and have a certain distance to the micro evaporation platform; the supporting beams are located between the micro evaporation platform and the anchor points, one end of each supporting beam is connected with the micro evaporation platform and the other end is connected with the anchor point; the size of each supporting beam satisfies the following relation: T=P(L/2kbh)+Tₐ; and the metal electrodes are located on first surfaces of the anchor points.

### BACKGROUND OF THE PRESENT INVENTION

### Field of Invention

The present invention belongs to the field of sensing technologies, and in particular relates to a micro evaporator, an oscillator integrated micro evaporator structure and a frequency correction method thereof.

### Description of Related Arts

An oscillator is a basic element for providing clock frequency in a digital electronic system, and is used in almost all electronic systems. In modern communication systems, since frequency resources are limited and users are numerous, an extremely high requirement is raised to the accuracy of oscillator frequency. GSM mobile phones require the frequency accuracy of oscillators to be within ±2.5 ppm, while mobile base stations require the stability of oscillators to be within ±0.05 ppm.

For a long time, quartz crystal oscillators are always main elements for providing clock frequency signals in electronic systems fonts stable performance and good temperature characteristic. However, quartz crystal oscillator is difficult to integrate quartz oscillators, it is difficult to manufacture high-frequency oscillators due to limitations of machining means, and the anti-vibration performance of quartz crystal oscillator is poor, thus it is difficult to satisfy the requirement of mobile intelligent devices.

Silicon-based oscillators are new-generation oscillators which are manufactured by adopting a Micro-Electro-Mechanical System (MEMS) technology, the resonance characteristic is excellent, the integration with integrated circuits is facilitated, GHz-level oscillation frequency output can be realized and they can tolerate high-impact environments,

One major problem which must be solved by oscillators is that the discreteness of MEMS oscillator frequency is caused to be great since the discreteness of MEMS machining is obviously greater than that of the traditional machining technologies. The machining accuracy of the traditional millimeter-level quartz crystal oscillators may reach a micron level, the quartz oscillators can work under the atmosphere, the frequency is corrected through processes such as testing and evaporation correction after machining, and extremely high frequency accuracy can be realized. However, oscillators are manufactured by adopting a wafer level machining process. The so-called wafer level manufacturing process refers to that there are hundreds, thousands and even several ten thousands of chip units on one silicon wafer, each chip unit is an independent component and all chip units on the wafer are simultaneously machined. Any manufacturing process has the problem of process discreteness on one wafer, the discreteness of processes such as oxidation and diffusion is relatively small, the discreteness of processes such as sputtering is close to 5% and the discreteness of etching is greater. The characteristic size of an MEMS oscillator is at a micron level, the process discreteness is generally at a submicron level, which results in the frequency discreteness of the manufactured oscillator is obviously greater than that of the quartz crystal oscillator manufactured by the traditional process. By performing manufacturability design to a resonance unit, the frequency discreteness of the oscillator may be reduced to a 102 ppm level. However, as compared with the ppm-level frequency discreteness of the quartz oscillator, there is still a significant difference. Target resonance frequency of oscillators is f₀±δf, wherein f₀ is a fixed frequency value satisfying an application demand and δf is a frequency deviation allowed by application. In common application, allowed δf/f₀ is at a 10⁻⁵-10⁻⁶ level; and however, the resonance frequency of silicon MEMS oscillators which are actually manufactured has great discreteness and a deviation of the resonance frequency f and f₀ of the oscillators is generally far greater than δf.

For the traditional quartz oscillators, a thin metal layer is manufactured on a surface of the resonance unit by adopting an evaporation or sputtering process, so as to change the mass of the resonance unit to realize frequency regulation. Since oscillators generally need to work in vacuum, the manufactured oscillators generally have already realized vacuum packaging through a wafer level packaging process, it is difficult to finely adjust the structure of each resonance unit packaged in the vacuum chamber by adopting the traditional method and consequently the frequency calibration of the oscillators cannot be realized by adopting the traditional technologies.

### SUMMARY OF THE PRESENT INVENTION

Aiming at the defects existing in the prior art, the purpose of the present invention is to provide a micro evaporator, an oscillator integrated micro evaporator structure and a frequency correction method thereof, which are used for solving the problem that the frequency discreteness of oscillators is great in the prior art, and the problems that it is difficult to finely adjust the structure of the resonance unit packaged in a vacuum chamber and the frequency calibration of oscillators cannot be realized since oscillators realize vacuum packaging through a wafer level packaging process.

In order to realize the above-mentioned purpose and other related purposes, the present invention provides a micro evaporator, and the micro evaporator comprises a micro evaporation platform, anchor points, supporting beams and metal electrodes, wherein:

one surface of the micro evaporation platform is an evaporation surface;

the anchor points are located on two sides of the micro evaporation platform and have a certain distance to the micro evaporation platform;

the supporting beams are located between the micro evaporation platform and the anchor points, one end of each supporting beam is connected with the micro evaporation platform and the other end is connected with the anchor point; the size of each supporting beam satisfies the following relation:

$$T = P \frac{L}{2 kbh} + {T}_{a}$$

where b, h and L are respectively width, thickness and length of the supporting beam, T is the desired evaporation temperature of the micro evaporation platform during working, P is power which needs to be applied to the metal electrode during working, k is heat conductivity of the supporting beam and Tₐ is temperature at the anchor point; and

the metal electrodes are located on first surfaces of the anchor points.

As a preferred solution of the micro evaporator provided by the present invention, saturated vapor pressure of a material of the micro evaporation platform at temperature lower than a melting point of the material is greater than 10⁻⁶ Torr.

As a preferred solution of the micro evaporator provided by the present invention, materials of the micro evaporation platform, the anchor points and the supporting beams are homogeneous silicon or germanium.

As a preferred solution of the micro evaporator provided by the present invention, the micro evaporator further comprises an evaporation material and the evaporation material is located on the evaporation surface of the micro evaporation platform.

As a preferred solution of the micro evaporator provided by the present invention, temperature of the evaporation material at saturated vapor pressure greater than 10⁻⁶ Torr is lower than the melting point of the micro evaporation platform.

As a preferred solution of the micro evaporator provided by the present invention, the evaporation material is aluminum, germanium, gold or a semiconductor material.

As a preferred solution of the micro evaporator provided by the present invention, the micro evaporator further comprises a blocking layer and the blocking layer is located between the evaporation material and the evaporation surface of the micro evaporation platform.

As a preferred solution of the micro evaporator provided by the present invention, a material of the blocking layer is low-stress silicon nitride, silicon oxide or TiW/W composite metal.

As a preferred solution of the micro evaporator provided by the present invention, the micro evaporator further comprises an insulating layer and a substrate, the insulating layer is located on second surfaces of the anchor points and the anchor points are fixedly connected to a surface of the substrate through the insulating layer.

The present invention further provides an oscillator integrated micro evaporator structure, and the oscillator integrated micro evaporator structure comprises the micro evaporator according to any one of the above-mentioned solutions and an oscillator; and

the micro evaporator and the oscillator are jointly sealed in the same vacuum chamber, the micro evaporator and the oscillator are correspondingly arranged from top to bottom, and the evaporation surface of the micro evaporation platform of the micro evaporator faces to the oscillator.

As a preferred solution of the oscillator integrated micro evaporator structure provided by the present invention, the evaporation surface of the micro evaporator has a certain distance to a surface of the oscillator.

As a preferred solution of the oscillator integrated micro evaporator structure provided by the present invention, the distance between the evaporation surface of the micro evaporator and the surface of the oscillator is 2 μm-50 μm.

As a preferred solution of the oscillator integrated micro evaporator structure provided by the present invention, the micro evaporator and the oscillator are integrated and sealed in the same vacuum chamber through a surface micro machining process, a wafer level bonding process, a chip and wafer bonding process or a chip level bonding process.

The present invention further provides a frequency correction method of an oscillator integrated micro evaporator structure, and the frequency correction method of the oscillator integrated micro evaporator structure comprises the following steps:

1) measuring resonance frequency of the oscillator and comparing the measured resonance frequency with target resonance frequency;

2) obtaining desired evaporation mass of the micro evaporator according to a result of comparison between the measured resonance frequency and the target resonance frequency;

3) applying voltage or current to the first metal electrodes at the two ends of the micro evaporator to enable the micro evaporator to evaporate the desired evaporation mass; and

4) removing the voltage or current applied to the first metal electrodes, measuring the resonance frequency of the oscillator again and comparing the measured resonance frequency with the target resonance frequency.

As a preferred solution of the frequency correction method of the oscillator integrated micro evaporator structure provided by the present invention, after step 4), the frequency correction method further comprises the step of repeating step 2) to step 4) till the measured resonance frequency is the same as the target resonance frequency.

The micro evaporator, the oscillator integrated micro evaporator structure and the frequency correction method thereof provided by the present invention have the following beneficial effects: the micro evaporation platform is connected with the anchor points with the metal electrodes formed on the surfaces through the supporting beams, and by adjusting and setting the size of the supporting beams, the supporting beams are enabled to have the features of small heat capacity and less heat dissipation; since the sizes of the micro evaporation platform and the supporting beam are small, the micro evaporation platform can be enabled to reach the desired evaporation temperature by applying very small power to the surfaces of the metal electrodes; due to the heat insulation effect of the supporting beams, the temperature rise at the anchor points is smaller and no influence is caused to the stability of the device; and by integrating the oscillator and the micro evaporator into the same vacuum chamber, the regulation and correction of the frequency of the oscillator are realized, the accuracy of the frequency of the oscillator can be improved and the application requirements are satisfied.

### BRIEF DESCRIPTION OF THE DRAWINGS

FIG. 1 illustrates a stereoscopic structural schematic view of a micro evaporator provided in embodiment 1 of the present invention.

FIG. 2 to FIG. 3 illustrate stereoscopic structural schematic views of a micro evaporator provided in embodiment 2 of the present invention.

FIG. 4 illustrates a stereoscopic structural schematic view of an oscillator integrated micro evaporator structure provided in embodiment 3 of the present invention.

FIG. 5 illustrates a stereoscopic structural schematic view of an oscillator integrated micro evaporator structure provided in embodiment 4 of the present invention.

FIG. 6 illustrates a stereoscopic structural schematic view of an oscillator integrated micro evaporator structure provided in embodiment 5 of the present invention.

FIG. 7 illustrates a stereoscopic structural schematic view of an oscillator integrated micro evaporator structure provided in embodiment 6 of the present invention.

FIG. 8 illustrates a stereoscopic structural schematic view of an oscillator integrated micro evaporator structure provided in embodiment 7 of the present invention.

FIG. 9 illustrates a stereoscopic structural schematic view of an oscillator integrated micro evaporator structure provided in embodiment 8 of the present invention.

FIG. 10 illustrates a stereoscopic structural schematic view of an oscillator integrated micro evaporator structure provided in embodiment 9 of the present invention.

FIG. 11 illustrates a stereoscopic structural schematic view of an oscillator integrated micro evaporator structure provided in embodiment 10 of the present invention.

FIG. 12 illustrates a sectional structural schematic view of an oscillator integrated micro evaporator structure provided in embodiment 10 of the present invention.

FIG. 13 illustrates a stereoscopic structural schematic view of an oscillator integrated micro evaporator structure provided in embodiment 11 of the present invention.

FIG. 14 illustrates a flowchart of a frequency correction method of an oscillator integrated micro evaporator structure provided in embodiment 12 of the present invention.

Description of component reference signs

| | |
|---|---|
| 11 | Micro evaporation platform |
| 12 | First anchor point |
| 121 | First sub-anchor point |
| 122 | Second sub-anchor point |
| 13 | First supporting beam |
| 14 | First metal electrode |
| 15 | Blocking layer |
| 16 | Evaporation material |
| 17 | First insulating layer |
| 21 | Resonance unit |
| 211 | First vibrating beam |
| 212 | Second vibrating beam |
| 22 | Second supporting beam |
| 23 | Second anchor point |
| 24 | Second metal electrode |
| 25 | Second insulating layer |
| 3 | First substrate |
| 41 | Third insulating layer |
| 42 | Second substrate |
| 51 | First sealing structure |
| 511 | First material layer |
| 512 | Fourth insulating layer |
| 52 | Second sealing structure |
| 521 | Second material layer |
| 522 | Fifth insulating layer |
| 53 | First solder layer |
| 54 | Second solder layer |
| 61 | Connecting strut |
| 611 | Third solder layer |
| 612 | Sixth insulating layer |
| 62 | Third solder layer |
| 63 | Fourth solder layer |
| 64 | Redistribution layer |
| 65 | Solder ball |
| 66 | First metal plug |
| 67 | Second metal plug |
| 7 | Seventh insulating layer |

### DETAILED DESCRIPTION OF THE PREFERRED EMBODIMENTS

The implementation modes of the present invention will be described below through specific examples. One skilled in the art can easily understand other advantages and effects of the present invention according to content disclosed in the description. The present invention may also be implemented or applied through other different specific implementation modes. Various modifications or variations may be made to all details in the description based on different points of view and applications without departing from the spirit of the present invention.

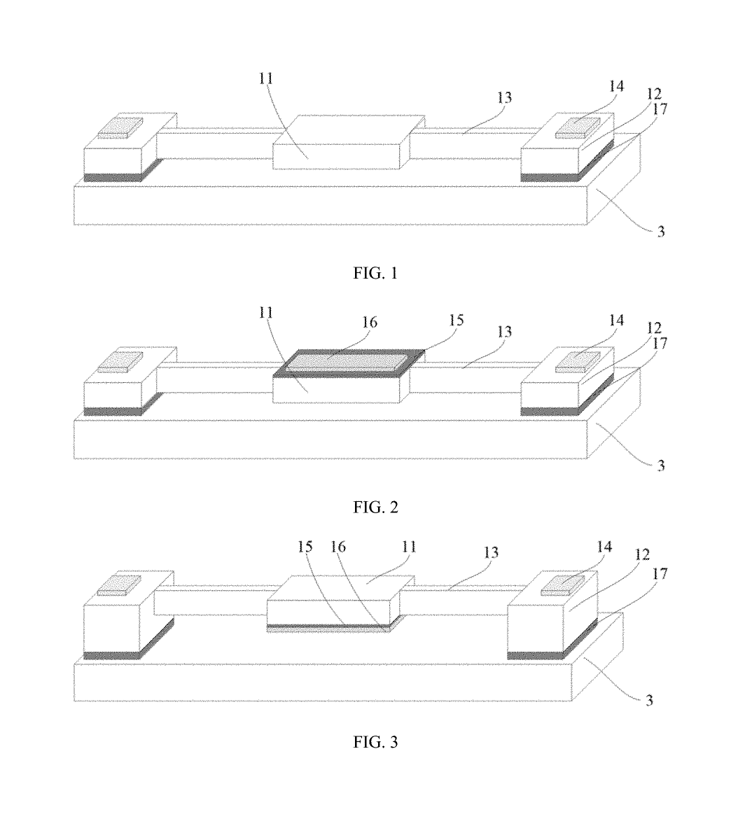

Please refer to FIG. 1 to FIG. 14. It needs to be stated that the drawings provided in the following embodiments are just used for schematically describing the basic concept of the present invention, thus only illustrate components only related to the present invention and are not drawn according to the numbers, shapes and sizes of components during actual implementation, the configuration, number and scale of each component during actual implementation thereof may be freely changed, and the component layout configuration thereof may be more complex.

### Embodiment 1

Please referring to FIG. 1, the present invention provides a micro evaporator, and the micro evaporator comprises a micro evaporation platform 11, anchor points, supporting beams and metal electrodes; in order to facilitate distinguishing from subsequent other structures, the anchor points, the supporting beams and the metal electrodes here are respectively defined as first anchor points 12, first supporting beams 13 and first metal electrodes 14;

one surface of the micro evaporation platform 11 is an evaporation surface; the first anchor points 12 are located on two sides of the micro evaporation platform 11 and have a certain distance to the micro evaporation platform 11; the first supporting beams 13 are located between the micro evaporation platform 11 and the first anchor points 12, one end of each first supporting beam 13 is connected with the micro evaporation platform 11 and the other end is connected with the first anchor point 12; the size (i.e., length, width and height) of each supporting beam 13 satisfies the following relation:

$$T = P \frac{L}{2 kbh} + {T}_{a} ,$$

where b, h and L are respectively width, thickness and length of the supporting beam, T is the desired evaporation temperature of the micro evaporation platform during working, P is power which needs to be applied to the metal electrode during working, k is heat conductivity of the supporting beam and Tₐ is temperature at the anchor point; and the first metal electrodes 14 are located on first surfaces of the first anchor points 12.

By designing the length, width and thickness of the first supporting beams 13, the power when the micro evaporator works can be designed. It needs to be stated that the premises the size of each first supporting beam 13 satisfies the relation

$$T = P \frac{L}{2 kbh} + {T}_{a}$$

are as follows: the first supporting beams 13 are two equally-long, equally-wide and equally-thick homogenous rectangular section beams, it is supposed that heat dissipation through vacuum radiation can be ignored and it is supposed that the temperature of the micro evaporation platform 11 is uniform. An accurate power-temperature relationship can be determined through experiments. The first supporting beams 13 are core structures of the micro evaporator and mainly play roles of heating while being electrified and decreasing heat conduction. When current is applied to the first supporting beams 13, since the width b, the thickness h and the length L of the first supporting beams 13 all are small in actual design, the first supporting beams 13 have the features of small heat capacity and less heat dissipation, the temperature of one end, close to the micro evaporation platform 11, of each first supporting beam 13 will rapidly rise, the temperature of the micro evaporation platform 11 rapidly rises therewith, the heat dissipated to the positions of the first anchor points 12 is less, the temperature rise of one end, close to the first anchor points 12, of each first supporting beam 13 is smaller, and the stability of the device will not be influenced.

As an example, as illustrated in FIG. 1, the micro evaporator is a self-evaporation micro evaporator, saturated vapor pressure of a material of the micro evaporation platform at temperature lower than a melting point of the material is greater than 10⁻⁶ Torr. Materials of the micro evaporation platform 11, the first anchor points 12 and the first supporting beams 13 all may be conductive materials, and the conductive materials may be semiconductor materials such as monocrystalline silicon, polycrystalline silicon, or germanium, or may be metal materials such as copper, which is commonly used in the packaging process. Preferably, the materials of the micro evaporation platform 11, the first anchor points 12 and the first supporting beams 13 all are monocrystalline silicon or polycrystalline silicon. More preferably, in this embodiment, the materials of the micro evaporation platform 11, the first anchor points 12 and the first supporting beams 13 all are heavily-doped monocrystalline silicon, and the doping type may be P-type or N-type. Silicon can realize higher saturated vapor pressure when the temperature is lower than the melting point. For example, the melting point of silicon is 1410° C., while the temperature when the saturated vapor pressure is 10⁻⁶ Torr is 1447° C. and the temperature when the saturated vapor pressure is 10⁻⁴ Torr is 1337° C. Silicon is used as the material of the micro evaporation platform 11, during working, voltage or current is applied to the first metal electrodes 14, the current passes through the first supporting beams 13 and the micro evaporation platform 11 to heat the first supporting beams 13 and the micro evaporation platform 11, the temperature of the micro evaporation platform 11 can be enabled to reach the temperature at the desired saturated vapor pressure by controlling the heating current power, and thus the micro evaporation platform 11 is enabled to self-evaporate.

As an example, as illustrated in FIG. 1, the first supporting beams 13 are, but not limited to, fixed-fixed beams, and the first supporting beams 13 may also be in various other forms such as folded beams.

As an example, the material of the first electrodes 14 may be, but not limited to, aluminum.

As an example, the micro evaporator further comprises an insulating layer and a substrate, the insulating layer is located on second surfaces of the first anchor points 12, and the first anchor points 12 are fixedly connected to a surface of the substrate through the insulating layer. In order to facilitate distinguishing from subsequent other structures, the insulating layer and the substrate here are respectively defined as first insulating layer 17 and first substrate 3.

Since the sizes of the first supporting beams 13 and the micro evaporation platform 11 are small, the heat capacity is also small. The micro evaporator is packaged in vacuum, very small power is only needed such that the temperature of the micro evaporation platform 11 and the end, close to the micro evaporation platform 11, of each first supporting beam 13 can be increased to be close to 1000° C. or even above 1000° C. Moreover, due to the heat insulation effect of the first supporting beams 13, the temperature rise at the first anchor points 12 is small and is obviously lower than the stable working temperature of the first metal electrodes 14, and the stability of the device is not influenced.

### Embodiment 2

Please referring to FIG. 2 to FIG. 3, the present invention further provides a micro evaporator, the structure of the micro evaporator is approximately the same as the structure of the micro evaporator in embodiment 1, and the micro evaporator in this embodiment differs from the micro evaporator in embodiment 1 in that:

the micro evaporator further comprises an evaporation material 16 and the evaporation material 16 is located on the evaporation surface of the micro evaporation platform 11.

As an example, when saturated vapor pressure is greater than 10⁻⁶ Torr, temperature of the evaporation material 16 is lower than the melting point of the micro evaporation platform 11. The evaporation material 16 may be selected to be metal, semiconductor or insulating materials, e.g., aluminum, germanium, gold or semiconductor materials such as silicon or germanium. The micro evaporator and the oscillator are integrally used to correct the resonance frequency of the oscillator, the selection of the evaporation material 16 needs to satisfy the following conditions: 1) the evaporation material can be deposited on the surface of the oscillator and the bonding strength thereof satisfies the application demand; 2) the evaporation material and the oscillator are stable in normal working environments, and the influences thereof on the frequency in long-term and short-term stability and aging rate of the oscillator satisfy the application demand; 3) the evaporation temperature is within a temperature range in which the first supporting beams 13 and the micro evaporation platform 11 can stably work, and the saturated vapor pressure of the evaporation material 16 should be far greater than the saturated vapor pressure of the micro evaporation platform 11 and the first supporting beams 13; and 4) the evaporation speed satisfies the requirement on frequency correction. For example, metal aluminum may be deposited on a silicon material and can stably work for a long term, the saturated vapor pressure is 10⁻⁶ Torr when the temperature is 821° C. and the saturated vapor pressure is 10⁻⁴ Torr when the temperature is 1010° C. Since the size of the oscillator is small, in partial design, the saturated vapor pressure of 10⁻⁶ can satisfy the need of frequency correction. Semiconductor germanium also can be deposited on a silicon material, the saturated vapor pressure is 10⁻⁶ Torr when the temperature is 957° C. and the saturated vapor pressure is 10⁻⁴ Torr when the temperature is 1167° C.

As an example, the micro evaporator further comprises a blocking layer 15, the blocking layer 15 is located between the evaporation material 16 and the evaporation surface of the micro evaporation platform 11, i.e., the blocking layer 15 is located on the evaporation surface of the micro evaporation platform 11 and the evaporation material 16 is located on the surface of the blocking layer 15. The blocking layer 15 plays a role of preventing the evaporation material 16 and the micro evaporation platform 11 from experiencing mutual diffusion or chemical reaction at the evaporation temperature, and the blocking layer 15 is also an adhesion layer of the evaporation material 16.

As an example, the blocking layer 15 may be selected to be insulating materials such as low-stress silicon nitride and silicon oxide, or may also be selected to be composite metal materials such as TiW/W.

It needs to be stated that, if the evaporation material 16 and the micro evaporation platform 11 do not experience mutual diffusion or chemical reaction at the evaporation temperature, the blocking layer 15 may be omitted.

As an example, the evaporation material 16 may be located on an upper surface of the micro evaporation platform 11 as illustrated in FIG. 2, or may also be located on a lower surface of the micro evaporation platform 11 as illustrated in FIG. 3.

### Embodiment 3

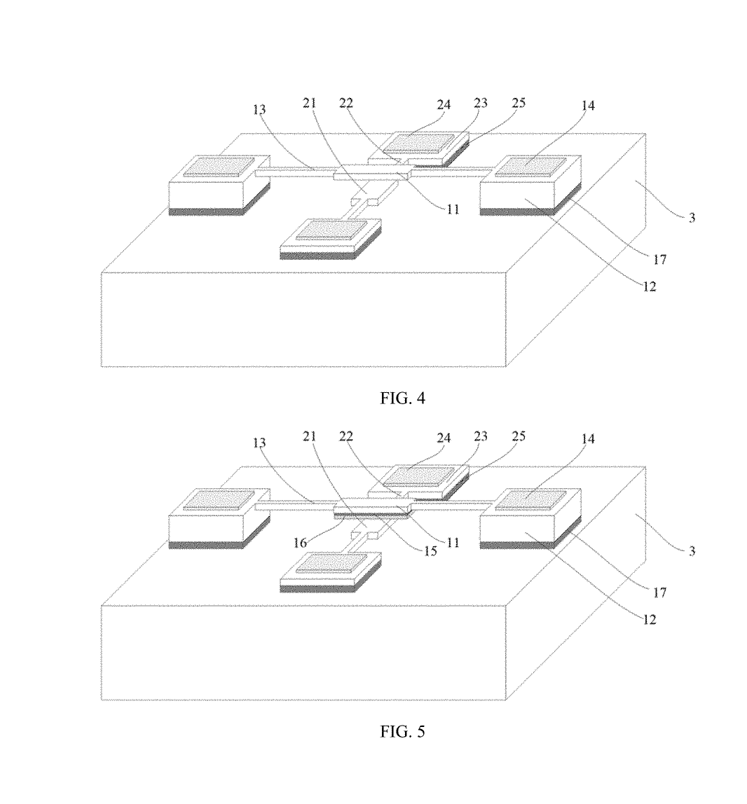

Please referring to FIG. 4, the present invention provides an oscillator integrated micro evaporator structure, and the oscillator integrated micro evaporator structure comprises the micro evaporator in embodiment 1 and an oscillator; and

the micro evaporator and the oscillator are jointly sealed in a same vacuum chamber, the micro evaporator and the oscillator are arranged in upper and lower correspondence, and the evaporation surface of the micro evaporation platform 11 in the micro evaporator faces to the oscillator.

As an example, the oscillator may be a quartz oscillator, or a silicon-based MEMS oscillator, or any one other oscillator, and the type and structure of the oscillator are not limited herein, i.e., the oscillator may be any one of existing oscillators.

In this embodiment, by taking a bending-mode oscillator as an example, the oscillator comprises a resonance unit 21, second supporting beams 22, second anchor points 23, and second metal electrodes 24. The resonance unit 21 is a mass block. The number of the second anchor points 23 is two, and the two second anchor points 23 are respectively located on the two sides of the resonance unit 21 and have a certain distance to the resonance unit 21. The second supporting beams 22 are located between the resonance unit 21 and the second anchor points 23, one end of each second supporting beam 22 is connected with the resonance unit 21, the other end is connected with the second anchor point 23, and the resonance unit 21 and the second supporting beams 22 jointly form a resonance structure; and the second metal electrodes 24 are located on first surfaces of the second anchor points 23.

As an example, a material of the second electrodes 24 may be, but not limited to, aluminum.

As an example, the oscillator integrated micro evaporator structure further comprises a second insulating layer 25. The second insulating layer 25 is located on second surfaces of the second anchor points 23, and the second anchor points 23 are fixedly connected to a front surface of the first substrate 3 through the second insulating layer 25. It needs to be stated that the first surface and the second surface of each second anchor point 23 are two opposite surfaces; and the resonance unit 21 and lower surfaces of the second supporting beams 22 have a certain distance to the upper surface of the first substrate 3, and the distance is the thickness of the first insulating layer 17.

As an example, the resonance unit 21, the second supporting beams 22, the second anchor points 23, the first anchor points 12, the first supporting beams 13 and the micro evaporation platform 11 may be formed of a same material, and may be integrally formed by etching the same material layer through a surface micro machining process.

As an example, the second supporting beams 22 are located below the first supporting beams 13, and perpendicular to the first supporting beams 13; and the micro evaporation platform 11 is located right above the resonance unit 21 and has a certain distance to the resonance unit 21, and preferably, in this embodiment, the distance therebetween is 2 μm-50 μm.

As an example, the number of the micro evaporation platforms 11 (i.e., the number of the micro evaporators) and the number of the resonance units 21 (i.e., the number of the oscillators) are the same. In FIG. 4, the number of the micro evaporation platform 11 and the number of the resonance unit 21 both are one, for example.

As an example, in order to improve the vacuum degree of the vacuum chamber, a getter may be arranged in the vacuum chamber.

By integrating the oscillator and the micro evaporator in a same vacuum chamber in a face-to-face manner and using the micro evaporator for evaporating to deposit the metal or semiconductor material onto the surface of the resonance unit 21, the equivalent mass of the resonance unit 21 can be permanently changed, the regulation and correction of the frequency of the oscillator can be realized, the resonance frequency of the oscillator can be permanently corrected to be within an error range (10⁻⁵-10⁻⁶) allowed for the target resonance frequency, the frequency accuracy of the oscillator can be improved and the application requirement is satisfied.

### Embodiment 4

Please referring to FIG. 5, the present invention further provides an oscillator integrated micro evaporator structure, the structure of the oscillator integrated micro evaporator structure is approximately the same as the structure of the oscillator integrated micro evaporator structure in embodiment 3, and a difference therebetween lies in that: the micro evaporator in embodiment 3 is the self-evaporation micro evaporator in embodiment 1, while the micro evaporator in this embodiment is the micro evaporator in embodiment 2, i.e., the blocking layer 15 and the evaporation material 16 are provided on the evaporation surface of the micro evaporation platform 11 in the micro evaporator. In FIG. 5, for example, the evaporation material 16 is located on the lower surface of the micro evaporation platform 11, i.e., the evaporation surface of the micro evaporation platform 11 is the lower surface.

### Embodiment 5

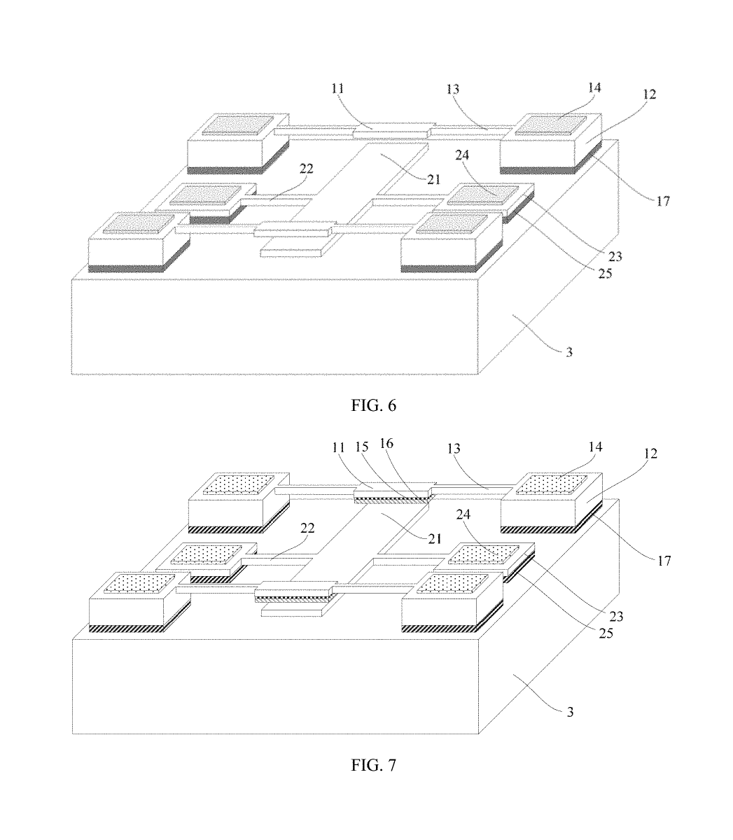

Please referring to FIG. 6, the present invention further provides an oscillator integrated micro evaporator structure, the structure of the oscillator integrated micro evaporator structure is approximately the same as the structure of the oscillator integrated micro evaporator structure in embodiment 3, and differences therebetween lie in that: 1) in embodiment 3, the oscillator is a bending-mode oscillator and the resonance unit 21 is a mass block; while in this embodiment, the oscillator is a stretching-mode oscillator, the resonance unit 21 is a plate structure and lateral sides of the resonance unit 21 are perpendicularly connected with the second supporting beams 22; 2) in embodiment 3, the second supporting beams 22 is perpendicular to the first supporting beams 13; while in this embodiment, the second supporting beams 22 and the first supporting beams 13 are in parallel; and 3) in embodiment 3, the number of the micro evaporation platform 11 and the number of the resonance unit 21 are the same, and both are one; while in this embodiment, the number of the resonance unit 21 is one, the number of the micro evaporation platforms 11 is two, and the two micro evaporation platforms 11 are respectively located at two ends of the resonance unit 21.

### Embodiment 6

Please referring to FIG. 7, the present invention further provides an oscillator integrated micro evaporator structure, the structure of the oscillator integrated micro evaporator structure is approximately the same as the structure of the oscillator integrated micro evaporator structure in embodiment 5, and a difference therebetween lies in that: the micro evaporator in embodiment 5 is the self-evaporation micro evaporator in embodiment 1, while the micro evaporator in this embodiment is the micro evaporator in embodiment 2, i.e., the blocking layer 15 and the evaporation material 16 are provided on the evaporation surface of the micro evaporation platform 11 of the micro evaporator. In FIG. 7, for example, evaporation material 16 is located on the lower surface of the micro evaporation platform 11, i.e., the evaporation surface of the micro evaporation platform 11 is the lower surface.

### Embodiment 7

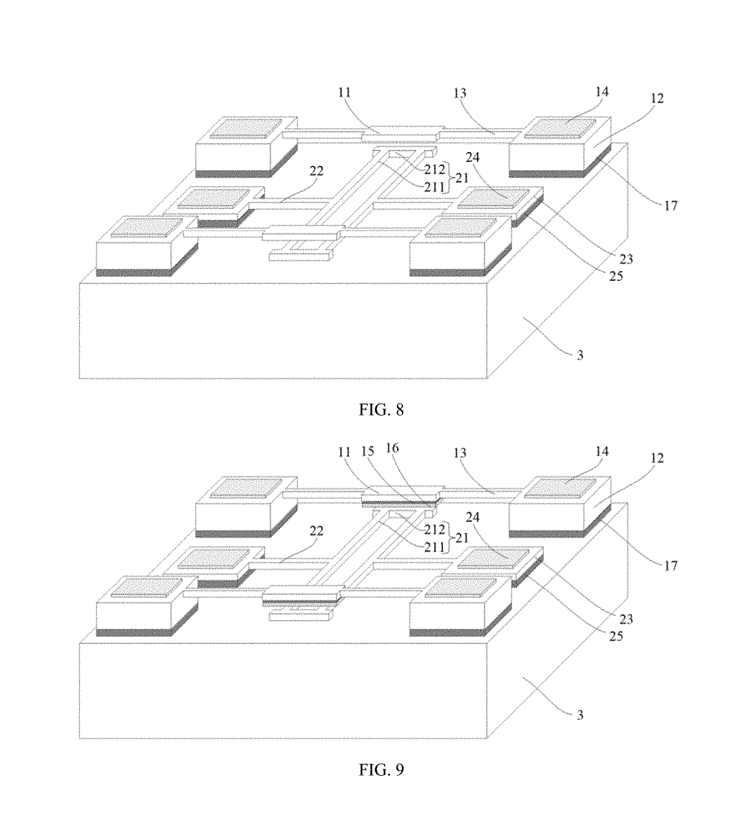

Please referring to FIG. 8, the present invention further provides an oscillator integrated micro evaporator structure, the structure of the oscillator integrated micro evaporator structure is approximately the same as the structure of the oscillator integrated micro evaporator structure in embodiment 5, and differences therebetween lie in that: in embodiment 5, the oscillator is a stretching-mode oscillator and the resonance unit 21 is a plate structure, while in this embodiment, the oscillator is a stretching-mode oscillator, the resonance unit 21 comprises first vibrating beams 211 and second vibrating beams 212, the first vibrating beams 211 are connected with the second supporting beams 22, the second vibrating beams 212 are located at two ends of the first vibrating beams 211, and the micro evaporation platforms 11 of the micro evaporator correspond to the second vibrating beams 212 one by one from top to bottom.

As an example, the number of the first vibrating beams 211 is two and the two first vibrating beams 211 are arranged in parallel; the second vibrating beams 212 are located at two ends of the first vibrating beams 211 and are perpendicularly connected with the first vibrating beams 211; and one ends of the second supporting beams 22 are perpendicularly connected to the middles of the first vibrating beams 211.

### Embodiment 8

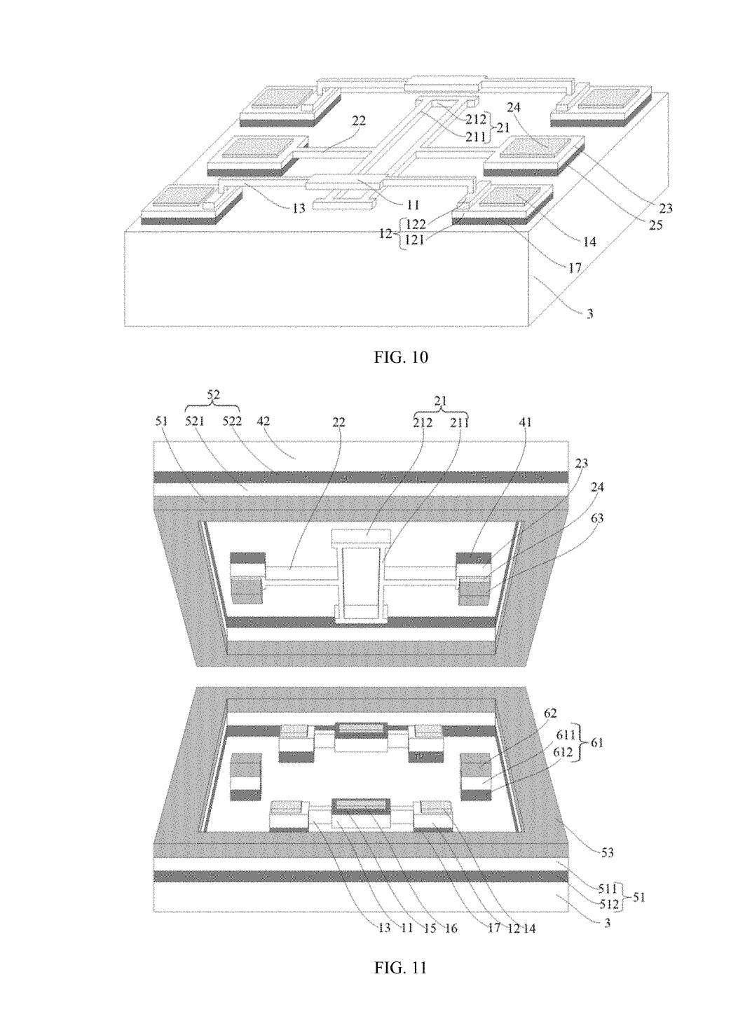

Please referring to FIG. 9, the present invention further provides an oscillator integrated micro evaporator structure, the structure of the oscillator integrated micro evaporator structure is approximately the same as the structure of the oscillator integrated micro evaporator structure in embodiment 7, and a difference therebetween lies in that: the micro evaporator in embodiment 7 is the self-evaporation micro evaporator in embodiment 1, while the micro evaporator in this embodiment is the micro evaporator in embodiment 2, i.e., the blocking layer 15 and the evaporation material 16 are provided on the evaporation surface of the micro evaporation platform 11 of the micro evaporator. In FIG. 9, the evaporation material 16 is located on the lower surface of the micro evaporation platform 11, for example, i.e., the evaporation surface of the micro evaporation platform 11 is the lower surface.

### Embodiment 9

Please referring to FIG. 10, the present invention further provides an oscillator integrated micro evaporator structure, the structure of the oscillator integrated micro evaporator structure is approximately the same as the structure of the oscillator integrated micro evaporator structure in embodiment 7, and a difference therebetween lies in that: each first anchor point 12 in embodiment 7 has a separate structure, while in this embodiment, each first anchor point 12 comprises a first sub-anchor point 121 and a second sub-anchor point 122, the first metal electrodes 14 and the second sub-anchor points 122 are located on first surfaces of the first sub-anchor points 121, and the second surfaces of the first sub-anchor points 121 are the second surfaces of the first anchor points 12; and the first supporting beams 13 are connected with the second sub-anchor points 122.

### Embodiment 10

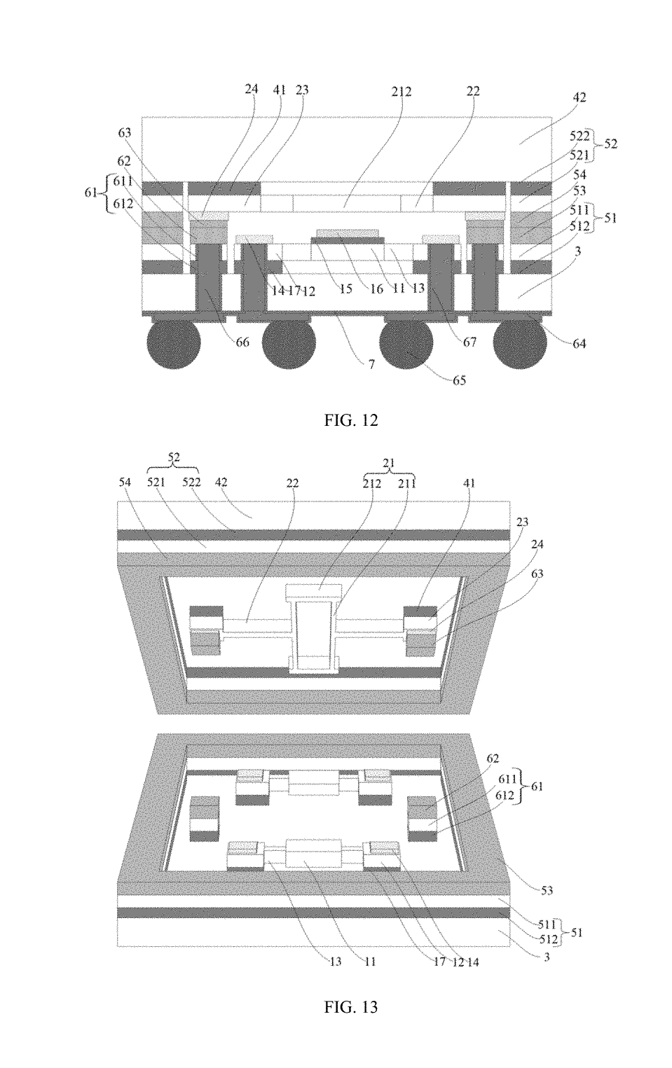

Please referring to FIG. 11 and FIG. 12, the present invention further provides an oscillator integrated micro evaporator structure, the structure of the oscillator integrated micro evaporator structure is approximately the same as the structure of the oscillator integrated micro evaporator structure in embodiment 8, and differences therebetween lie in that: 1) in embodiment 8, the oscillator integrated micro evaporator structure only comprises the first substrate 3, and the oscillator and the micro evaporator both are integrated on the surface of the first substrate 3; while in this embodiment, the oscillator integrated micro evaporator structure further comprises a third insulating layer 41 and a second substrate 42; the third insulating layer 41 is located on the second surfaces of the second anchor points 23 and the second anchor points 23 are fixedly connected to the surface of the second substrate 42 through the third insulating layer 41; and 2) in embodiment 8, the evaporation surface of the micro evaporation platform 11 is the lower surface thereof, i.e., the evaporation material 16 is located on the lower surface of the micro evaporation platform 11, while in this embodiment, the evaporation surface of the micro evaporation platform 11 is the upper surface thereof, i.e., the surface deviating from the first substrate 3, also i.e., the evaporation material 16 is located on the upper surface of the micro evaporation platform 11, as illustrated in FIG. 11 and FIG. 12. Compared with embodiment 4, this embodiment further comprises the following features:

The oscillator integrated micro evaporator structure further comprises a first sealing structure 51, a second sealing structure 52, a first solder layer 53 and a second solder layer 54; the first sealing structure 51 is located on the front surface of the first substrate 3 and is located on the periphery of the micro evaporator; the second sealing structure 52 is located on the surface of the second substrate 42, and is located on the periphery of the oscillator and corresponds to the first sealing structure 51 from top to bottom; the first solder layer 53 is located on the surface of the first sealing structure 51, the second solder layer 54 is located on the surface of the second sealing structure 52, and the first substrate 3 and the second substrate 42 are soldered together through the first solder layer 53 and the second solder layer 54 to form the vacuum chamber between the first substrate 3 and the second substrate 42.

The first sealing structure 51 comprises a first material layer 511 and a fourth insulating layer 512; the first material layer 511 is fixedly connected to the front surface of the first substrate 3 through the fourth insulating layer 512, the first solder layer 53 is located on the surface of the first material layer 511; the second sealing structure 52 comprises a second material layer 521 and a fifth insulating layer 522; and the second material layer 521 is fixedly connected to the surface of the second substrate 42 through the fifth insulating layer 522, and the second solder layer 54 is located on the surface of the second material layer 521.

The oscillator integrated micro evaporator structure further comprises connecting struts 61, a third solder layer 62, a fourth solder layer 63, a redistribution layer 64, solder balls 65, first metal plugs 66 and second metal plugs 67. The connecting struts 61 are located on the front surface of the first substrate 3 and correspond to the second metal electrodes 24 one to one from top to bottom. The third solder layer 62 is located on the surfaces of the connecting struts 61, the fourth solder layer 63 is located on the surfaces of the second metal electrodes 24. The third solder layer 62 and the fourth solder layer 63 are soldered together. The redistribution layer 64 is located on the back surface of the first substrate. The solder balls 65 are located on the surface of the redistribution layer 64. The first metal plugs 66 penetrate through the first substrate 3 and the connecting struts 61, one ends the first metal plugs 66 are connected with the third solder layer 62, and the other ends are connected with the rewiring layer 64. The second metal plugs 67 penetrate through the first substrate 3, the first insulating layer 17, and the first anchor points 12, one ends of the second metal plugs 67 are connected with the first metal electrodes 14 and the other ends are connected with the redistribution layer 64, i.e., the second metal electrodes 24 of the oscillator are electrically led out through the fourth solder layer 63, the third solder layer 62, the first metal plugs 66, the redistribution layer 64 and the solder balls 65. The first metal electrodes 14 of the micro evaporator is electrically led out through the second metal plugs 67, the redistribution layer 64 and the solder balls 65. The first metal plugs 66 and the second metal plugs 67 may be formed together through the same process step, and the materials thereof are the same and may be, but not limited to, copper or aluminum.

The connecting struts 61 comprise a third material layer 611 and a sixth insulating layer 612; and the third material layer 611 is fixedly connected to the front surface of the first substrate 3 through the sixth insulating layer 612, and the third solder layer 62 is located on the surface of the third material layer 611.

As an example, the materials of the first solder layer 53, the second solder layer 54, the third solder layer 62 and the fourth solder layer 63 may be, but not limited to, aluminum-germanium alloy.

The oscillator integrated micro evaporator structure further comprises a seventh insulating layer 7, and the seventh insulating layer 7 is located between the first metal plugs 66, the first substrate 3 and the connecting struts 61, is located between the second metal plugs 67, and the first substrate 3, the first insulating layer 17 and the first anchor points 12, is located between the first substrate 3 and the redistribution layer 64, and is located on the surface, on which the solder balls 65 are not formed, of the redistribution layer 64.

As an example, the oscillator integrated micro evaporator structure in this embodiment is manufactured by adopting two SOI silicon wafers, and each SOI silicon wafer sequentially comprises a silicon substrate, a buried oxide layer and top silicon from bottom to top, wherein the first substrate 3 and the second substrate 42 both are silicon substrates; the first insulating layer 17, the third insulating layer 41, the fourth insulating layer 512, the fifth insulating layer 522 and the sixth insulating layer 612 all are machined by adopting the buried oxide layer; and the resonance unit 21, the second supporting beams 22, the second anchor points 23, the second material layer 512, the micro evaporation platform 11, the first supporting beams 13, the first anchor points 12, the first material layer 511 and the third material layer 611 all are machined by adopting the top silicon.

### Embodiment 11

Please referring to FIG. 13, the present invention further provides an oscillator integrated micro evaporator structure, the structure of the oscillator integrated micro evaporator structure is approximately the same as the structure of the oscillator integrated micro evaporator structure in embodiment 10, and a difference therebetween lies in that: the micro evaporator in embodiment 10 is the micro evaporator in embodiment 2, while the micro evaporator in this embodiment is the self-evaporation micro evaporator in embodiment 1.

### Embodiment 12

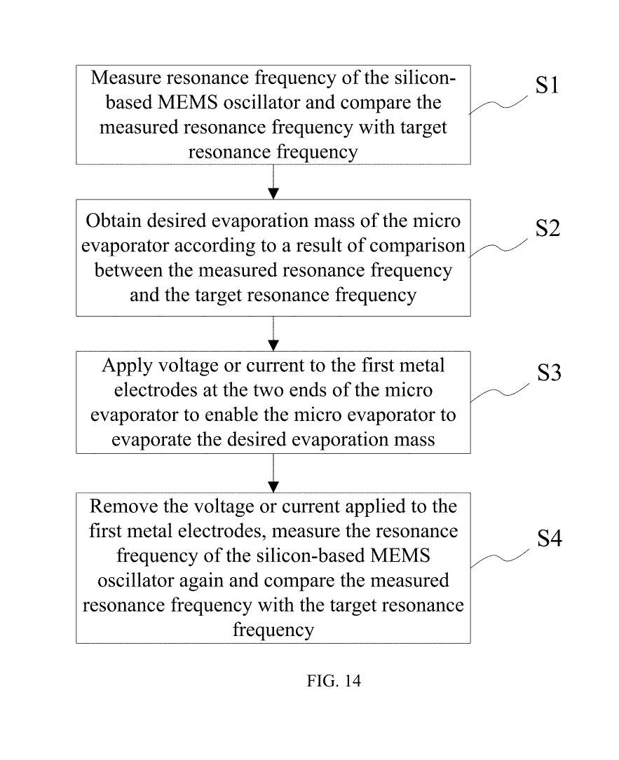

Please referring to FIG. 14, the present invention further provides a frequency correction method of the oscillator integrated micro evaporator structure in any one of the above-mentioned embodiments, and the frequency correction method of the oscillator integrated micro evaporator structure comprises the following steps:

1) measuring resonance frequency of the oscillator and comparing the measured resonance frequency with target resonance frequency;

2) obtaining desired evaporation mass of the micro evaporator according to a result of comparison between the measured resonance frequency and the target resonance frequency;

3) applying voltage or current to the first metal electrodes at the two ends of the micro evaporator to make the micro evaporator evaporate the desired evaporation mass; and

4) removing the voltage or current applied to the first metal electrodes, measuring the resonance frequency of the oscillator again and comparing the measured resonance frequency with the target resonance frequency.

Please referring to step S1 in FIG. 14, resonance frequency of the oscillator is measured and the measured resonance frequency is compared with target resonance frequency.

As an example, the resonance frequency of the silicon-based MEMS oscillator may be measured by existing measuring method. The resonance unit is generally a complex elastic body in the above-mentioned embodiments and comprises infinite resonance modes, however, for any resonance mode i, the resonance characteristics approximately satisfy the following equation:

m_{ieff}\ddot{x}+c_{ieff}\dot{x}+k_{ieff}x=0

where m_{ieff} is i-mode equivalent mass, c_{ieff} is i-mode equivalent damping coefficient, k_{ieff} is i-mode equivalent coefficient of stiffness and x is amplitude of resonance unit. The equivalent mass and the equivalent coefficient of stiffness can be obtained through mechanic calculation methods such as Rayleigh-Ritz method. The i-mode resonance frequency is:

$${f}_{i} = \frac{1}{2 π} \sqrt{\frac{{k}_{ieff}}{{m}_{ieff}}}$$

When the equivalent mass m_{ieff} increases, the resonance frequency fᵢ of the resonance unit will decrease. In order to guarantee that the micro evaporator can effectively correct the resonance frequency of the resonance unit to reach the target value, the resonance frequency of the resonance unit should be guaranteed to be slightly higher than the target value during design, and the resonance frequency of the resonance unit is corrected to the target value through the integrated micro evaporator at the testing stage after manufacturing.

When the mass block in embodiment 2 is used as a resonance unit and a transverse first-order bending mode is adopted as a working mode of the resonance unit, the equivalent mass is approximately equal to the mass of the mass block, i.e., m_{ieff}=m, and the equivalent coefficient of stiffness is approximately equal to the coefficient stiffness of two fixed-fixed beams,

$$i . e . , {k}_{ieff} = \frac{2 {Ehb}^{3}}{{L}^{3}} ,$$

where E is Young's modulus, h is beam thickness, b is beam width and L is beam length.

The oscillator in embodiment 3 is a stretching-mode oscillator, the equivalent mass in this mode is

$${k}_{ieff} = \frac{Ebh}{l} ,$$

the equivalent coefficient of stiffness is

$${m}_{ieff} = \frac{4 ρ bhl}{{π}^{2}} ,$$

ρ is density,

E is Young's modulus, and h is structure thickness.

Please refer to step S2 in FIG. 14, desired evaporation mass of the micro evaporator is obtained according to a result of comparison between the measured resonance frequency and the target resonance frequency.

As an example, a formula for calculating the desired evaporation mass for correction is:

$$Δ m = {m}_{eff} \times \frac{{f}_{i}^{2} - {f}_{0}^{2}}{{f}_{0}^{2}}$$

where m_{ieff} is i-mode equivalent mass, fᵢ is resonance frequency of resonance unit and f₀ is fixed frequency value satisfying application demand.

Please referring to step S3 in FIG. 14, voltage or current is applied to the first metal electrodes at the two ends of the micro evaporator to make the micro evaporator evaporate the desired evaporation mass.

As an example, voltage is applied to two ends of the micro evaporator to enable the temperature the silicon material micro evaporation platform or the evaporation material on the surface of the micro evaporation platform of the micro evaporation to increase and reach the set evaporation temperature, and at this moment the silicon material micro evaporation platform or the evaporation material will be evaporated and deposited on the surface of the oscillator. Since the micro evaporation platform faces to the resonance unit and the gap is at a micron level, silicon atoms or the evaporation material is mainly deposited on the surface of the resonance unit.

Please referring to step S4 in FIG. 14, the voltage or current applied to the first metal electrodes is removed, the resonance frequency of the oscillator is measured again and the measured resonance frequency is compared with the target resonance frequency.

As an example, if the resonance frequency measured in step 4) is the same as the target resonance frequency, the correction is ended; and if the resonance frequency measured in step 4) is still deviated from the target resonance frequency, step 2) to step 4) are repeated till the measured resonance frequency is the same as the target resonance frequency.

To sum up, the present invention provides a micro evaporator, an oscillator integrated micro evaporator structure and a frequency correction method thereof. The micro evaporator comprises: a micro evaporation platform, one surface of the micro evaporation platform being an evaporation surface; anchor points located on two sides of the micro evaporation platform and having a certain distance to the micro evaporation platform; supporting beams located between the micro evaporation platform and the anchor points, one end of each supporting beam being connected with the micro evaporation platform and the other end being connected with the anchor point; and metal electrodes located on first surfaces of the anchor points. The micro evaporation platform is connected with the anchor points with the metal electrodes formed on the surfaces through the supporting beams, and by adjusting and setting the size of the supporting beams, the supporting beams are enabled to have the features of small heat capacity and less heat dissipation; since the sizes of the micro evaporation platform and the supporting beam are small, the micro evaporation platform can be enabled to reach the desired evaporation temperature by applying very small power to the surfaces of the metal electrodes; due to the heat insulation effect of the supporting beams, the temperature rise at the anchor points is smaller and no influence is caused to the stability of the device; and by integrating the oscillator and the micro evaporator into the same vacuum chamber, the regulation and correction of the frequency of the oscillator are realized, the accuracy of the frequency of the oscillator can be improved and the application requirements are satisfied.

The above-mentioned embodiments are just used for exemplarily describing the principle and effect of the present invention instead of limiting the present invention. One skilled in the art may make modifications or changes to the above-mentioned embodiments without departing from the spirit and scope of the present invention. Therefore, all equivalent modifications or changes made by those who have common knowledge in the art without departing from the spirit and technical thought disclosed by the present invention shall be still covered by the claims of the present invention.

1. A micro evaporator, characterized in that the micro evaporator comprises a micro evaporation platform, anchor points, supporting beams and metal electrodes, wherein:
one surface of the micro evaporation platform is an evaporation surface;
the anchor points are located on two sides of the micro evaporation platform and have a certain distance to the micro evaporation platform;
the supporting beams are located between the micro evaporation platform and the anchor points, one end of each supporting beam is connected with the micro evaporation platform and the other end is connected with the anchor point; the size of each supporting beam satisfies the following relation:
$$T = P \frac{L}{2 kbh} + {T}_{a}$$
where b, h and L are respectively width, thickness and length of the supporting beam, T is the desired evaporation temperature of the micro evaporation platform during working, P is power which needs to be applied to the metal electrode during working, k is heat conductivity of the supporting beam and Tₐ is temperature at the anchor point; and
the metal electrodes are located on first surfaces of the anchor points.

2. The micro evaporator according to claim 1, characterized in that saturated vapor pressure of a material of the micro evaporation platform at temperature lower than a melting point of the material is greater than 10⁻⁶ Torr.

3. The micro evaporator according to claim 2, characterized in that materials of the micro evaporation platform, the anchor points and the supporting beams are homogeneous silicon or germanium.

4. The micro evaporator according to claim 1, characterized in that the micro evaporator further comprises an evaporation material, and the evaporation material is located on the evaporation surface of the micro evaporation platform.

5. The micro evaporator according to claim 4, characterized in that temperature of the evaporation material at saturated vapor pressure greater than 10⁻⁶ Torr is lower than the melting point of the micro evaporation platform.

6. The micro evaporator according to claim 5, characterized in that the evaporation material is aluminum, germanium, gold or a semiconductor material.

7. The micro evaporator according to claim 5, characterized in that the micro evaporator further comprises a blocking layer, the blocking layer is located between the evaporation material and the evaporation surface of the micro evaporation platform.

8. The micro evaporator according to claim 7, characterized in that a material of the blocking layer is low-stress silicon nitride, silicon oxide or TiW/W composite metal.

9. The micro evaporator according to claim 1, characterized in that the micro evaporator further comprises an insulating layer and a substrate, the insulating layer is located on second surfaces of the anchor points and the anchor points are fixedly connected to a surface of the substrate through the insulating layer.

10. An oscillator integrated micro evaporator structure, characterized in that the oscillator integrated micro evaporator structure comprises the micro evaporator according to claim 1 and an oscillator; and
the micro evaporator and the oscillator are jointly sealed in a same vacuum chamber, the micro evaporator and the oscillator are correspondingly arranged from top to bottom, and the evaporation surface of the micro evaporation platform in the micro evaporator faces to the oscillator.

11. The oscillator integrated micro evaporator structure according to claim 10, characterized in that the evaporation surface of the micro evaporator has a certain distance to a surface of the oscillator.

12. The oscillator integrated micro evaporator structure according to claim 11, characterized in that the distance between the evaporation surface of the micro evaporator and the surface of the oscillator is 2 μm-50 μm.

13. The oscillator integrated micro evaporator structure according to claim 10, characterized in that the micro evaporator and the oscillator are integrated and sealed in a same vacuum chamber through a surface micro machining process, a wafer level bonding process, a chip and wafer bonding process or a chip level bonding process.

14. A frequency correction method of the oscillator integrated micro evaporator structure according to claim 10, characterized in that the frequency correction method comprises the following steps:
1) measuring resonance frequency of the oscillator and comparing the measured resonance frequency with target resonance frequency;
2) obtaining desired evaporation mass of the micro evaporator according to a result of comparison between the measured resonance frequency and the target resonance frequency;
3) applying voltage or current to the first metal electrodes at the two ends of the micro evaporator to enable the micro evaporator to evaporate the desired evaporation mass; and
4) removing the voltage or current applied to the first metal electrodes, measuring the resonance frequency of the oscillator again and comparing the measured resonance frequency with the target resonance frequency.

15. The frequency correction method of the oscillator integrated micro evaporator structure according to claim 14, characterized in that, after step 4), the frequency correction method further comprises the step of repeating step 2) to step 4) till the measured resonance frequency is the same as the target resonance frequency.
